(19) United States
(12) Patent Application Publication
(10) Pub. No.: US 2006/0042679 A1
(43) Pub. Date: Mar. 2, 2006

(54) Self-contained portable solar power supply system

(76) Inventors: Kueun Choi, Trumbull, CT (US); Kue Byung Choi, Trumbull, CT (US)

Correspondence Address: Dr. Kueun Choi;5 Camelot Dr., P.O. Box 591, Trumbull, CT, 06611, US

(21) Appl. No.: 10/925,058

(22) Filed: Aug. 24, 2004

(51) Int. Cl. H01L 25/00

(52) U.S. Cl. 136/244; 136/251; 136/293

(57) ABSTRACT

A self-contained portable solar power supply system is specifically designed to convert solar energy into electrical energy, and charge a rechargeable storage battery to energize edge-lit lighted panels as back-lighting devices in the dusk to illuminate advertising graphics and messages installed on waste receptacles disposed on the city street curbs. The stored electrical energy is discharged by a dual control of a 24-hour timer unit and a photo light sensor control unit on a daily basis. To conserve the electrical energy consumption, the photo light sensor control unit is super-imposed as a second control over the time schedule of the 24-hour timer unit to ensure that the electrical energy will be discharged only when the photo light sensor control unit detects the light conditions in the immediate area diminish below a predetermined minimum light level setting. The photo light sensor control unit alleviates the need to reset the 24-hour timer unit as the local sunset time changes year-round. The rechargeable storage battery is protected by a power charge control unit against over-discharging the electrical energy below a predetermined voltage protection level of the rechargeable storage battery.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION-FIELD OF INVENTION

The present invention generally pertains to portable power supply systems and more specifically, to a self-contained portable solar power supply system.

### BACKGROUND OF THE INVENTION

The present invention relates to a self-contained portable solar power supply system. It is designed to supply electrical power to illuminate advertising graphic and message displays that are attached to four edge-lit lighted panels installed on waste receptacles placed at locations without ready access to public utility power supply.

In recent years, an innovative approach in advertising displays has transformed the waste receptacles on the city street curbs into billboards displaying promotional graphics and messages. Utilizing the exterior spaces of such waste disposal containers as billboards is a novel idea that has been well received by the business and local communities alike. However, illuminating the advertising graphic and message displays on them in the dusk is a very challenging task because the waste receptacles must be transportable and have the functional capacity to be lighted at any location without ready access to public utility power supply. Such waste receptacles must also be adaptable to be conveniently placed in rest areas in public and entertainment parks, public parking lots and the like out of the reach of public utility power supply. Therefore, the only logical solution is to supply electrical power using batteries to illuminate the advertising graphic displays on the waste receptacles. Recharging such batteries from sunlight to maintain the power charge levels necessary to illuminate advertising graphic displays is constrained by the size of a solar cell panel that can be installed on the limited space available on the top cover of the waste receptacles.

The patent search for the present invention focused on self-contained solar power supply systems and their applications. Summarized below are outstanding U.S. patents issued in this particular field:

U.S. Pat. No. 3,317,809 issued to Bowers et al. sets forth a SELF-CONTAINED ELECTRICAL LIGHTING UNIT comprising a bank of solar cells as a power source, a battery periodically charged thereby, a light, a two-way electromagnetic relay or switch, and a second bank of solar cells as a power source for energizing and de-energizing the relay to move its switch blade to one position and permit it to move under spring bias to the other, respectively. It is to provide a novel self-contained electrical lighting unit, which periodically recharges the light power source from sunlight and is adapted for a wide range of uses, particularly in areas where there is no source of standard electrical power or other power source of electrical light.

U.S. Pat. No. 4,009,535 issued to Stock sets forth an ILLUMINATED HOUSE SIGN which charges an internal battery from photo-voltaic cells during daylight. The battery is connected to a lamp via a phototransistor for energizing the lamp at night. The lamp lights a plastic template having cutout house number indicia.

U.S. Pat. No. 4,200,904 issued to Doan sets forth a SOLAR POWERED STREET LIGHTING SYSTEM that is totally independent of any external power supply. Solar panels are connected in such a manner to charge a maintenance free storage battery with sufficient capacity to light streetlights and/or traffic signals. An auxiliary generator may also be provided having a wind driven vane for also charging the battery if sufficient sunlight is not available.

U.S. Pat. No. 4,281,369 issued to Batte sets forth a METHOD AND APPARATUS FOR SOLAR POWER LIGHTING for utilization in conjunction with commercial light pole configurations incorporating conventional, hollow, upstanding light pole structures. More particularly, one aspect of the invention includes a remote solar panel array disposed about a light pole for tracking orientation relative to the sun for following the sun and supplying maximum power to a network of storage batteries disposed within an underlying, hollow light pole assembly.

U.S. Pat. No. 4,319,310 issued to Kingsley sets forth SOLAR SIGNS utilizing incident solar energy employing solar cells or thermal absorbers for generating electricity which is stored and later used for energizing sign illuminating lamp or lamps.

U.S. Pat. No. 4,486,820 issued to Baba et al. sets forth a LIGHTING EQUIPMENT WITH A SOLAR CELL that is adapted for outdoor location, the equipment being supported on a structure on which a solar cell is placed to charge up a battery for lighting a lamp, wherein the battery and the lamps are provided in the structure, the lamp being lit from the sunset up to the expiry of a predetermined period of time.

U.S. Pat. No. 5,542,203 issued to Luoma et al. sets forth a MOBILE SIGN WITH SOLAR PANEL comprising a wheeled vehicle, an electrically powered sign panel mounted on the wheeled vehicle, a chargeable battery for powering the sign panel, and a solar panel for charging the battery. The sign panel is independently rotate-able relative to the wheeled vehicle. The sign has a solar panel, which is tilt-able and rotate-able relative to the frame of the wheeled vehicle, thus making it easy to change the angle of the solar panel relative to the sun. The most electricity is generated from a solar panel when the sun's rays are perpendicular to the face of the solar panel.

Among the seven outstanding U.S. patents cited above, U.S. Pat. No. 4,486,820 issued to Baba et al. comes closest to the technical concept and design of the present invention with an important difference in the method of activating the beginning of electrical power usage of the waste receptacle lighting systems.

### SUMMARY OF THE INVENTION

The present invention relates to a self-contained portable solar power supply system specifically designed to energize back-lighting devices to illuminate advertising graphics and messages installed on the waste receptacles placed on the city street curbs, the rest areas of public and entertainment parks and public parking lots. On these locations, any ready access to public utility power supply is normally unavailable to outside vendors.

Therefore, the only logical solution to supply electrical power to illuminate the advertising graphic displays on the waste receptacles is to operate off batteries. The object of the present invention is to create a self-contained portable solar power supply system to generate electrical energy during the day-light hours from the solar panel installed on the top cover of the waste receptacles and store the electrical energy in the rechargeable storage battery for use during evening hours

The present invention utilizes the 24-hour timer unit and the photo light sensor control unit to turn on and off the electric current from the rechargeable storage battery. To conserve the electrical energy consumption, the photo light sensor control is super-imposed as a second control over the time schedule of the 24-hour timer unit to ensure that the electrical energy will be discharged only when the photo light sensor control unit detects the light condition in the immediate area diminishes below a predetermined minimum light level setting. Therefore the photo light sensor control unit alleviates the need to reset the 24-hour timer unit to synchronize with the local sunset time year-round.

### BRIEF DESCRIPTION OF THE DRAWINGS

The aforementioned objects and advantages of the present invention will be appreciated from the following description and accompanying drawings wherein:

FIG. 1 is a perspective view of an waste receptacle showing a solar panel on its top cover and two edge-lit lighted panels attached to its two visible sides.

FIG. 2 is a block diagram of the electric circuit of a preferred embodiment of the self-contained portable solar power system.

### DESCRIPTION OF THE PREFERRED EMBODIMENTS

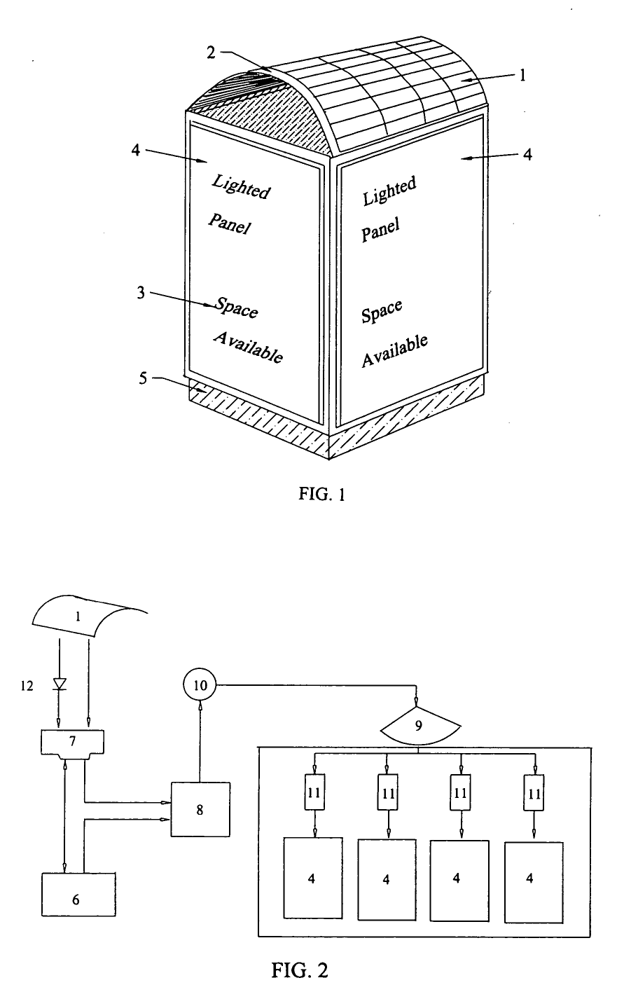

In FIG. 1, a perspective view of a waste receptacle is illustrated to show the solar cell panel 1 installed on its top cover 2, and two edge-lit lighted panels 4 for advertising graphic displays 3 attached to its two visible sides. A rechargeable storage battery 6 is housed inside the base 5 of the waste receptacle along with a power charge control unit 7, a 24-hour timer unit 8, and an output sequence control unit 9. A photo light sensor control 10 is attached to the structural frame behind one of the four-lighted panels to avoid direct exposure to any streetlights in the vicinity.

The solar cell panel 1 over the top cover 2 of the waste receptacle, while exposed to the sun light, generates electrical energy and charges the rechargeable storage battery 6 via a diode 12 and the power charge control unit 7. The diode 12 is adapted to prevent a reverse electric current flow from the rechargeable storage battery 6 back to the solar cell panel 1. The power charge control unit 7 regulates an output voltage of the solar cell panel 1 to an input voltage of 12 volt into the rechargeable storage battery 6. The solar cell panel 1 continues to generate electrical energy in a varying degree of efficiency in response to its exposure to the sun light subject to changing cloud formations through out the day.

The 24-hour timer unit 8 and the photo light sensor control unit 10 together impose a dual control on the flow of the stored electrical energy from the rechargeable storage battery 6. The 24-hour timer unit 8 can be programmed to turn on from, say, 5:00 p.m. to 1:00 a.m. throughout the year. However, the photo light sensor control 10, operating during this preset time period of the 24-hour timer unit, will evaluate the local daylight condition against a predetermined minimum light level setting before it allows the electric current to flow from the rechargeable storage battery 6 to the output sequence control unit 9. Because of this dual control configuration, the photo light sensor control 10 alleviates the need to reset the 24-hour timer unit 8 as the local sunset time changes year-round. The rechargeable storage battery 6 is also protected by the power charge control unit 7 against over-discharging the electrical energy below a predetermined voltage protection level of the storage battery 6.

In the preferred embodiment in FIG. 2, four edge-lit lighted panels 4 are connected to the output sequence control unit 9 by way of four corresponding inverters 11. When the four edge-lit lighted panels 4 are attached to the four specifically designed wall panels of a waste receptacle, and are connected to the self-contained portable solar power supply system, those four edge-lit lighted panels 4 will take a turn in sequence to turn on and off, and will illuminate the advertising graphic displays attached to them.

However, the relative time intervals of the on-and-off periods of the output sequence control unit 9 can be calibrated to balance the electrical power generation rate of the solar cell panel and the electrical power consumption rate of the four edge-lit lighted panels or any other applications. The flow of the electric current distributed by the output sequence control unit will power the four edge-lit lighted panels installed on the waste receptacle to illuminate the advertising graphic displays attached to them to attract the attention of passers-by.

We claim:

1. A self-contained portable solar power supply system comprising:
a) At least one solar cell panel, a power charge control unit and at least one rechargeable storage battery;
b) A first circuit connecting said solar cell panel with said rechargeable storage battery by way of said power charge control unit to allow electric current to flow from said solar cell panel to said rechargeable storage battery;
c) A 24-hour timer unit, a photo light sensor control unit and an output sequence control unit;
d) A second circuit connecting said rechargeable storage battery with said output sequence control unit by way of said 24-hour timer unit and said photo light sensor control unit; and
e) An over-discharge preventing means to prevent said rechargeable storage battery from over-discharging below a predetermined voltage protection level of said rechargeable storage battery.

2. A self-contained portable solar power supply system as in claim 1, wherein said 24-hour timer unit turns on and off according to a predetermined time schedule the electric current flows from said rechargeable storage battery to said output sequence control unit subject to said photo light sensor control unit;

3. A self-contained portable solar power supply system as in claim 1, wherein said photo light sensor control unit, operating within a predetermined time period of said 24-hour timer unit, turns on the flow of said electric current from said rechargeable storage battery to said output sequence control unit when the daylight conditions in the vicinity diminish below a predetermined light control setting; and

4. A self-contained portable solar power supply system as in claim 1, wherein said output sequence control unit distributes electric current from said rechargeable storage battery to intended power supply applications according to a preset switching sequence.
